(19) United States
(12) Patent Application Publication
(10) Pub. No.: US 2022/0415721 A1
(43) Pub. Date: Dec. 29, 2022

(54) Radiation Control in Semiconductor Processing

(71) Applicant: Taiwan Semiconductor Manufacturing Co., Ltd., Hsinchu City (TW)

(72) Inventors: Yu-Chun TAI, Hsinchu City (TW); Ta-Ching YANG, Hsinchu City (TW); Chung-Yi SU, Hsinchu City (TW); Ping-Cheng LU, Taichung City (TW); Ming-Feng LEE, Hsinchu City (TW)

(73) Assignee: Taiwan Semiconductor Manufacturing Co., Ltd., Hsinchu City (TW)

(21) Appl. No.: 17/738,293

(22) Filed: May 6, 2022

Related U.S. Application Data
(60) Provisional application No. 63/214,436, filed on Jun. 24, 2021.

(51) Int. Cl. H01L 21/66; H01L 21/324

(52) U.S. Cl. CPC H01L 22/20; H01L 21/324

(57) ABSTRACT

The present disclosure describes a method for controlling radiation conditions and an example system for performing the method. The method includes sending a first setting to configure a radiation device to provide radiation to a substrate undergoing a process operation in a process chamber of the radiation device. The method further includes receiving radiation energy data measured at a plurality of locations of the process chamber and receiving measurement data measured on the substrate during the process operation. The method further includes in response to a variance of the radiation energy data being above a first predetermined threshold and in response to a difference between reference data and the measurement data being above a second predetermined threshold, sending a second setting to configure the radiation device to provide radiation to the substrate.

### CROSS-REFERENCE TO RELATED APPLICATION

This application claims the benefit of U.S. Provisional Patent Application No. 63/214,436, filed on Jun. 24, 2021 and titled “A Novel Radiation Process Apparatus and Method,” the disclosure of which is incorporated by reference herein in its entirety.

### BACKGROUND

Some semiconductor process operations can be performed in radiation devices. For example, epitaxial growth of silicon (Si) can use halogen lamps as the radiation source. Rapid thermal anneal (RTA) and rapid thermal processing (RTP) can be used to grow oxides or improve doping uniformity. Both RTA and RTP can use halogen lamps as the radiation source. Ultraviolet (UV) lamps can be used as the radiation source to reduce organic contaminants on a wafer. Radiation non-uniformity can increase fabrication complexity and decrease yield.

### BRIEF DESCRIPTION OF THE DRAWINGS

Aspects of the present disclosure are best understood from the following detailed description when read with the accompanying figures.

FIG. 1 illustrates a diagram of a radiation control system, in accordance with some embodiments.

FIG. 2 illustrates a diagram of a detection device, in accordance with some embodiments.

FIG. 3 illustrates a diagram of an adjustment device, in accordance with some embodiments.

FIG. 4 is a flow diagram of a method for controlling radiation conditions, in accordance with some embodiments.

FIGS. 5A-7C illustrate various applications of a radiation control method, in accordance with some embodiments.

FIG. 8 illustrates a diagram of a computing device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the embodiments and/or configurations discussed herein.

Spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

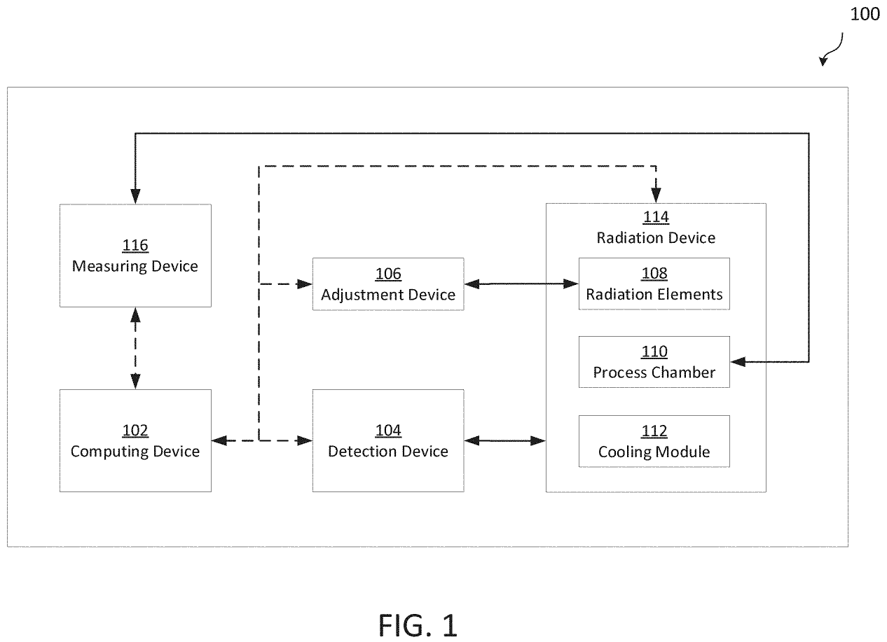

The discussion of elements in FIGS. 1-3 and 5A-8 with the same annotations applies to each other, unless mentioned otherwise.

Radiation devices can be used to perform some semiconductor process operations. A radiations device can include a process chamber, where the process operations can be performed, and one or more radiation elements as the radiation source. For example, epitaxial growth of a semiconductor material, such as silicon (Si) and silicon germanium (SiGe), can use halogen lamps as the radiation source. Reactant gases can react in the epitaxy process system to grow the epitaxy utilizing the radiation energy from the halogen lamps. Rapid thermal anneal (RTA) and rapid thermal processing (RTP) can be used to grow oxides or improve doping uniformity. Both RTA and RTP can use halogen lamps as the radiation source. In some embodiments, ambient oxygen can react with a Si substrate in the RTA/RTP process system to form silicon oxide (SiOₓ) utilizing the radiation energy from the halogen lamps. In some embodiments, ambient oxygen can react with a metal substrate in the RTA/RTP process system to form metal oxide (MOₓ) utilizing the radiation energy from the halogen lamps. In some embodiments, a protective gas, such as argon (Ar) and nitrogen (N2), can be introduced in the RTA/RTP process system to protect a substrate from oxidation while dopants, such as phosphorous (P) and boron (B), diffuse in the substrate utilizing the radiation energy from the halogen lamps. Ultraviolet (UV) lamps can be used as the radiation source to reduce organic contaminants on a substrate, such as a wafer. The radiation energy from the UV lamps can induce contaminant oxidation on the substrate placed in the UV process system, therefore reducing the amount of organic contaminants on the substrate. Conditions, such as the age of the radiation elements, the resistance of the radiation elements, and the tilt angles of the radiation elements, can affect the radiation energy distribution in the process chamber. Radiation non-uniformity can increase fabrication complexity and decrease yield. Challenges can exist for radiation control in the radiation devices.

The present disclosure is directed to a method for providing radiation control in radiation devices based on radiation energy data and substrate measurement data feedback and an example system for performing the method. A computing device can provide an initial radiation setting to a radiation device. The initial radiation setting can be based on temperature data collected on a test substrate equipped with one or more thermal sensors. The initial radiation setting can be additionally and/or alternatively based on measurement data collected on a test substrate that has completed a process operation of interest. The radiation device can provide radiation to a substrate, such as a production wafer, based on the initial radiation setting. Detection devices can be placed at different locations in the radiation device and collect radiation energy data. One exemplary detection device can include an optical fiber and a photodetector. The computing device can analyze the radiation energy data. If a variance of the radiation energy data is above a predetermined threshold, indicating the radiation energy distribution or non-uniformity is unacceptable, the computing device can adjust the radiation setting and provide the adjusted radiation setting to the radiation device. The radiation device can provide adjusted radiation based on the adjusted radiation setting to the substrate in substantially real time. The radiation device can also provide adjusted radiation based on the adjusted radiation setting to a subsequent substrate, where the subsequent substrate has yet to undergo the process operation. The radiation device can adjust radiation in different ways. For example, an adjustment device can be used to adjust a tilt angle of a radiation element. One exemplary adjustment device can include a motor, such as a stepper motor, a spring, and a lever. In some embodiments, the radiation device can adjust a resistance of a radiation element. In some embodiments, the radiation device can generate an instruction to replace an aged radiation element.

Additionally and/or alternatively, substrate measurement data feedback can be used to control radiation conditions. After the substrate completes the process operation, a measuring device can collect data, such as critical dimension (CD) data, on the substrate. The measurement data can include optical metrology data, optical inspection data, profilometer data, spectrometry data, electrochemical impedance spectroscopy (EIS) data, scanning electron microscopy (SEM) data, transmission electron microscopy (TEM) data, and a combination thereof. In some embodiments, the measurement data can be thickness data of an epitaxial layer on the substrate. In some embodiments, the measurement data can be thickness data of an oxide layer on the substrate. In some embodiments, the measurement data can be dopant concentration data of a doped layer on the substrate. In some embodiments, the measurement data can be contamination percentage data of the substrate. The computing device can analyze the measurement data. If a difference between reference data and the measurement data on the substrate is above another predetermined threshold, also indicating the radiation energy distribution or non-uniformity is unacceptable, the computing device can further adjust the radiation setting and provide the adjusted radiation setting to the radiation device. The radiation device can then provide adjusted radiation based on the further adjusted radiation setting to a subsequent substrate. In some embodiments, the measurement device can collect in-situ data on the substrate, and the radiation device can provide adjusted radiation based on the further adjusted radiation setting to the substrate in substantially real time. In some embodiments, the radiation device can analyze the radiation energy data and the measurement data and adjust the radiation setting itself. The method and example system in the present disclosure can improve radiation distribution and uniformity in substantially real time. The improved radiation uniformity can reduce fabrication complexity, reduce defects, improve yield, and improve device reliability.

According to some embodiments, FIG. 1 illustrates a diagram of a radiation control system 100. Radiation control system 100 can include a computing device 102, a detection device 104, an adjustment device 106, a radiation device 114, and a measuring device 116. Radiation device 114 can include one or more radiation elements 108, a process chamber 110, and a cooling module 112. Radiation control system 100 can be used to perform radiation control method 400, which is described below.

Computing device 102 can provide radiation settings to configure radiation device 114 to provide radiation to a substrate. The substrate can be located in process chamber 110, such as a on a substrate holder. The radiation settings can be provided to radiation device 114 by wired and/or wireless means, which can include local area networks (LANs), wide area networks (WANs), the Internet, wireless fidelity (Wi-Fi), Bluetooth, cable, optical fiber, and any combination thereof. Computing device 102 can receive the radiation energy data detected by one or more detection devices 104 placed at different locations in process chamber 110. Computing device 102 can receive the measurement data measured by measuring device 116 on the substrate. The radiation energy data and the measurement data can be provided to computing device 102 by wired and/or wireless means. Computing device 102 can analyze the radiation energy data and the measurement data and adjust the radiation settings. In some embodiments, computing device 102 can feed the radiation energy data and the measurement data into one or more mathematical models, and the mathematical models can adjust the radiation settings based on predetermined constraints and goals. In some embodiments, the mathematical models can be multiple regression analysis models. In some embodiments, the mathematical models can be linear regression models. Based on the adjusted radiation settings, computing device 102 can send instructions to adjustment device 106 to adjust a tilt angle or a resistance of radiation element 108. The instructions can be sent to adjustment device 106 by wired and/or wireless means. In some embodiments, computing device 102 can send instructions to replace an aged radiation element 108. The instructions can be displayed on an output means, such as a monitor, of computing device 102.

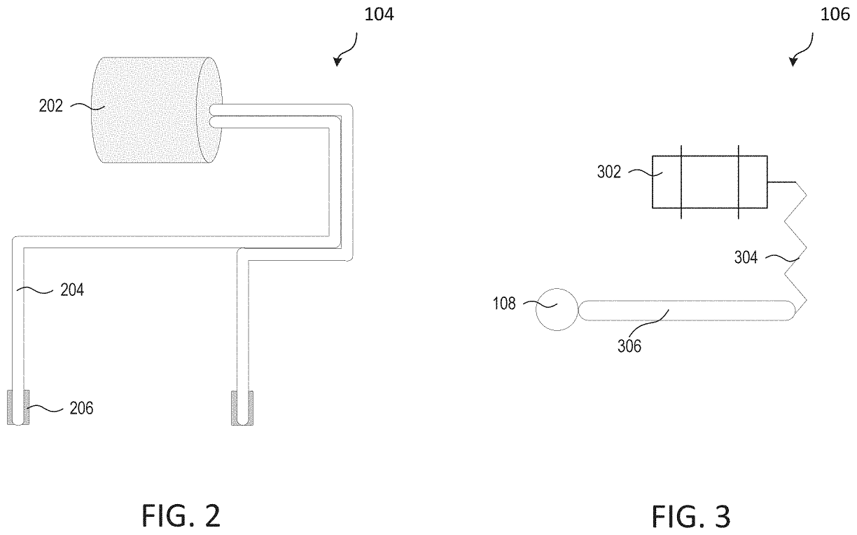

Detection device 104 can detect radiation energy data, such as in Joules, or temperature data, such as in Celsius, at different locations of radiation device 114, and can provide the radiation energy data to computing device 102. Detection device 104 can be installed in radiation device 114. Referring to FIG. 2, in some embodiments, detection device 104 can include photodetector 202, optical fiber 204, and coating layer 206. Photodetector 202 can detect photons and convert photons to a characterization of the radiation energy. In some embodiments, photodetector 202 can convert photons to an electric current and normalize the electric current as the characterization of the radiation energy. In some embodiments, photodetector 202 can employ mechanisms, such as photoelectric effect and phonon/heat generation, to characterize the radiation energy. In some embodiments, photodetector 202 can be a semiconductor-based photodetector, such as a p-n junction.

Optical fiber 204 can collect photons from its end. Light can be confined in optical fiber based on total internal reflection, and once collected, few photons can escape from optical fiber 204. Total internal reflection can ensure that the radiation energy is characterized for the location where the end of optical fiber 204 is placed. The number of optical fibers 204 can be between about 3 and about 50. If the number of optical fibers 204 is below about 3, the radiation energy uniformity data can be non-representative. If the number of optical fibers 204 is above about 50, the implementation of detection device 104 can be complicated. In some embodiments, all optical fibers 204 can connect to one photodetector 202. In some embodiments, optical fibers 204 can be divided into groups, where each group of optical fibers 204 can connect to one photodetector 202. Optical fiber 204 can withstand a temperature up to about 475 degrees Celsius. In some embodiments, optical fiber 204 is placed in cooling module 112 such that cooling module 112 can protect optical fiber 204 from high temperature. Each optical fiber 204 can be replaced if its lifetime has been reached. In some embodiments, optical fiber can be SiOₓ.

Coating layer 206 can protect optical fiber 204 such that detection device 104 can withstand a higher temperature than without coating layer 206. In some embodiments, optical fiber 204 with coating layer 206 can withstand a temperature up to about 700 degrees Celsius. Coating layer 206 can allow detection device 104 to be used in a greater variety of radiation devices. Coating layer 206 can be a metal, such as copper (Cu), aluminum (Al), nickel (Ni), gold (Au), and silver (Ag). In some embodiments, detection device 104 can include additional elements. In some embodiments, detection device 104 can include thermal sensors.

Referring to FIG. 1, adjustment device 106 can adjust a parameter, such as the tilt angle, of radiation element 108. Adjustment device 106 can receive instructions from computing device 102 to adjust radiation element 108. Adjustment device 106 can be installed in radiation device 114. Referring to FIG. 3, in some embodiments, adjustment device 106 can include motor 302, spring 304, and lever 306. Motor 302 can be a stepper motor, such as a permanent magnet stepper, a variable reluctance stepper, and a hybrid synchronous stepper. Motor 302 can have steps per revolution (SPR) between about 4 and about 400. A higher SPR can deliver a more precision adjustment of radiation element 108. Spring 304 can be any suitable spring, such as a compression, extension, torsion, and constant force spring. Spring 304 can be made of metal. Lever 306 can be any suitable lever, such as a first class, second class, and third class lever. Lever 306 can be made of metal or plastic. In some embodiments, adjustment device 106 can include connection elements, such as screws, rivets, and bolts. In some embodiments, adjustment device 106 can include additional elements. FIG. 3 is one exemplary configuration of adjustment device 106. In some embodiments, adjustment device 106 can include more than one motor 302, more than one spring 304, and more than one lever 306. For example, one exemplary adjustment device 106 can include four motors 302, four springs 304, and one lever 306. In some embodiments, adjustment device 106 can also have a configuration without a motor, a spring, or a lever to achieve the adjustment function. In some embodiments, adjustment device 106 can provide a lateral, a vertical, a rotational, or a tilting adjustment to radiation element 108. In some embodiments, adjustment device 106 can adjust other parameters, such as the resistance, of radiation element 108.

Referring to FIG. 1, radiation device 114 can include one or more radiation elements 108, process chamber 110, and cooling module 112. Radiation elements can be any suitable radiation source, such as halogen lamps and UV lamps. The number of radiation elements 108 can be between about 1 and about 100, depending on the predetermined use. Multiple radiation elements 108 can be arranged in different patterns, such as a line, a triangle, a rectangle, a concentric circle, an ellipse, a diamond, and a trapezoid. Radiation elements 108 can be connected to adjustment device 106 such that the tilt angle or the resistance of radiation elements 108 can be controlled. Radiation elements 108 can be controlled by other control mechanisms, such as by voltage standby (VSB). VSB can regulate the electrical supplies to radiation elements to adjust the radiation energy output. Radiation device 114 can also include an electric fan to regulate the process chamber temperature.

Process chamber 110 can perform a manufacturing process on a substrate placed in the chamber. The manufacturing process can be an anneal process, an oxidation process, an epitaxy process, a deposition process, and an etching process. Process chamber 110 can include a substrate holder and a mechanism to secure the substrate onto the substrate holder. The mechanism can be a vacuum suction mechanism and a mechanical support mechanism. Process chamber 110 can include a transfer module or a loading port to receive and return the substrate. The transfer module can deliver the substrate from a substrate carrier to process chamber 110 and return the substrate to the substrate carrier. In some embodiments, the transfer module can deliver the substrate from process chamber 110 to measuring device 116. The transfer module can be equipped with a robotic arm. The robotic arm can have multiple degrees of freedom. The robotic arm can include a vacuum suction mechanism such that the substrate can be secured on the robotic arm during transfers between different devices. In some embodiments, process chamber 110 can include a gas supply device and a vacuum pump. The gas supply device can supply process gas, protective gas, and carrier gas to process chamber 110. The vacuum pump can extract exhaust gas and maintain a predetermined vacuum level in process chamber 110. Process chamber 110 can include chamber walls, including a top wall, a bottom wall, and sidewalls. Process chamber 110 can include additional elements.

Cooling module 112 can reduce overheating of radiation device 114. Cooling module 112 can include a water cooling system and recycled water can absorb excess heat and reduce overheating. Cooling module 112 can include a cooling system using other liquid or gas coolants. Cooling module 112 can be a fan. Cooling module 112 can be integrated in radiation device 114 at locations where cooling module 112 can carry away excess heat efficiently. Detection device 104 can be embedded or encapsulated by cooling module 112 such that detection device 104 can sustain a high temperature. In some embodiments, cooling module 112 can be omitted.

Radiation device 114 can include exterior chamber walls, including a top wall, a bottom wall, and sidewalls, in addition to the process chamber walls. Radiation device 114 can include a reflector to concentrate radiation energy emitted by radiation elements 108. The reflector can be flat or curved. The reflector can be installed at or near a top wall, a bottom wall, top and bottom walls, or sidewalls of radiation device 114 or process chamber 110. Radiation device 114 can include radiation window, such as a quartz window. The quartz window can separate radiation elements 108 from process chamber 110. The quartz window can allow radiation energy to emit into process chamber 110. The quartz window can be installed at a top portion, a bottom portion, or both top and bottom portions of radiation device 114. Radiation device 114 can include additional elements. Radiation device 114 can be connected to adjustment device 106, detection device 104, and measuring device 116. Radiation device 114 can receive the radiation settings from computing device 102 by wired and/or wireless means. In some embodiments, radiation device 114 can receive the radiation energy data and the measurement data, analyze the radiation energy data and the measurement data, and adjust the radiation settings itself.

Measuring device 116 can measure measurement data, such as CD, of structures on a substrate. Measuring device 116 can be an optical metrology device, an optical inspection device, a profilometer, an EIS, an SEM, a TEM, or other suitable measuring tools. In some embodiments, the measurement can be in-situ or substantially in real time. Measuring device 116 can include a loading port to receive and return the substrate. In some embodiments, the loading port can receive the substrate from process chamber 110 and return the substrate to process chamber 110. In some embodiments, the loading port can receive the substrate from a substrate carrier and return the substrate to the substrate carrier. One or more sites can be measured across each substrate by measuring device 116. Multiple measurement sites can provide CD uniformity information across each substrate. Measuring device 116 can be a stand-alone device. Measuring device 116 can transmit the measurement data to computing device 102 by wired and/or wireless means. Some exemplary measurement data include thickness data of an epitaxial layer on the substrate, thickness data of an oxide layer on the substrate, dopant concentration data of a doped layer on the substrate, and contamination percentage data of the substrate.

Additional devices can be included in radiation control system 100 and are omitted for simplicity. These additional devices are within the spirit and the scope of this disclosure. Moreover, not all devices may be required to perform the disclosure provided herein.

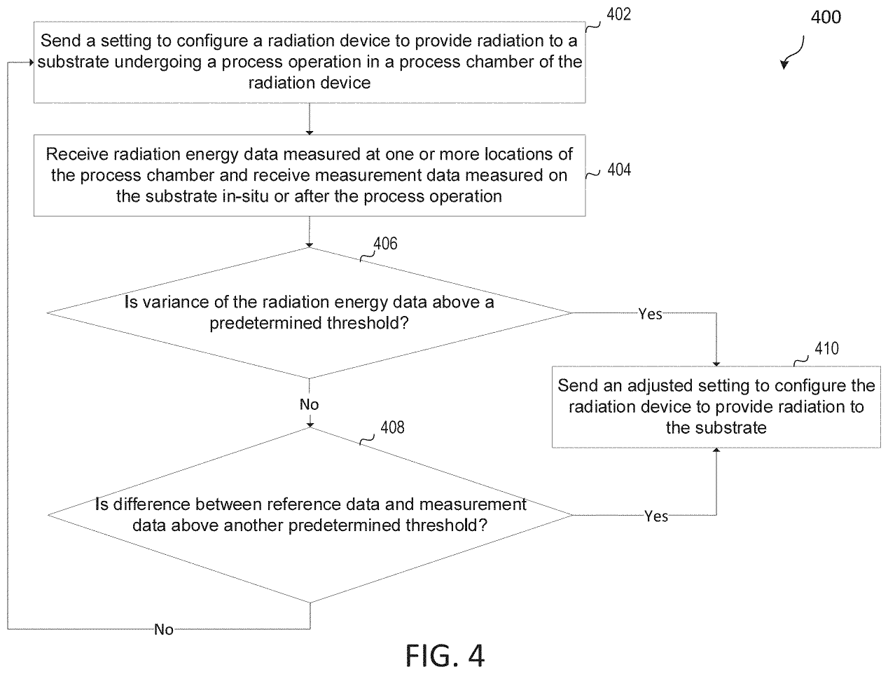

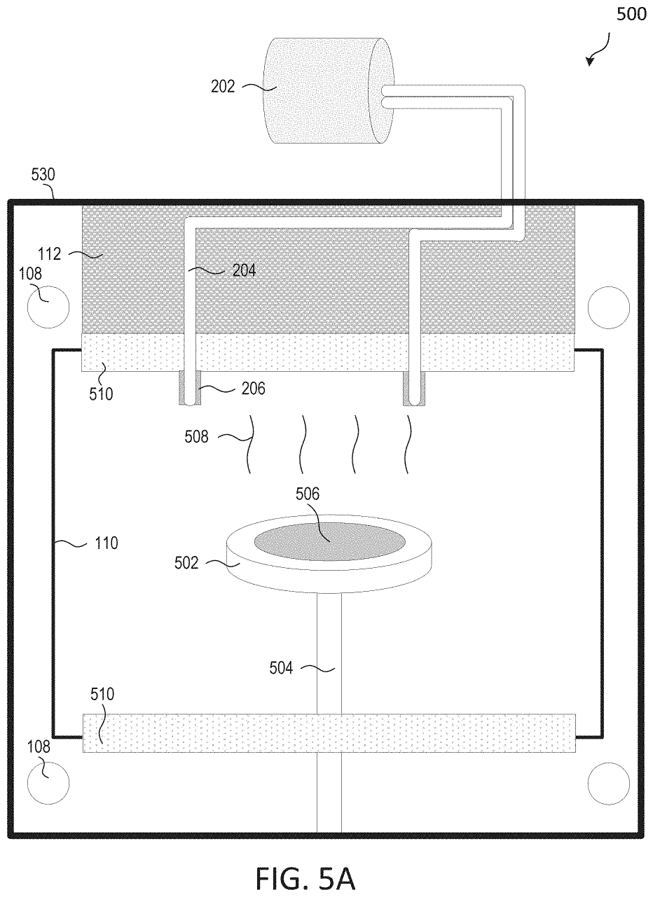

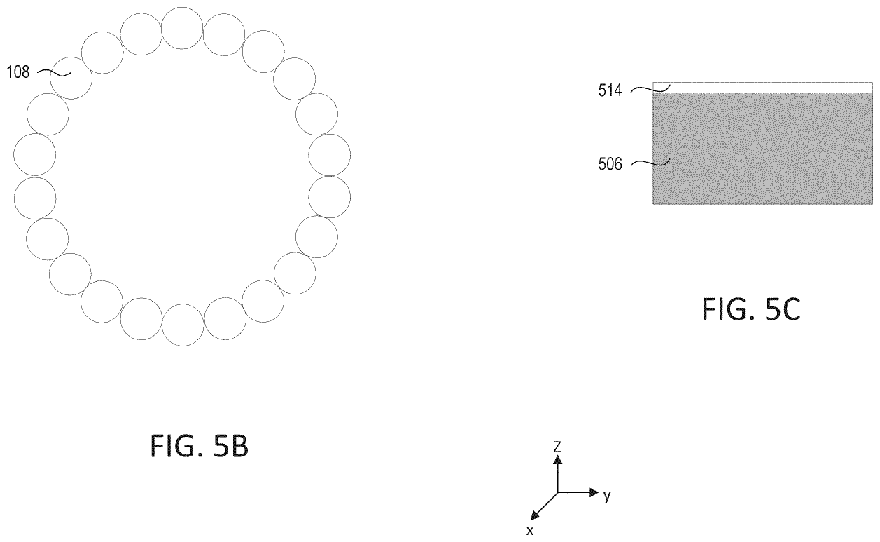

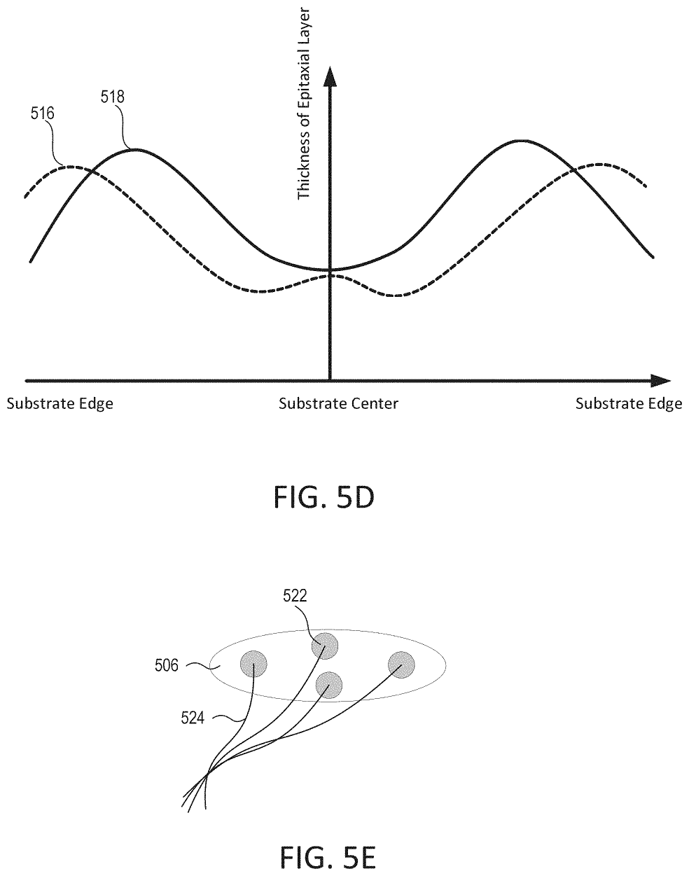

According to some embodiments, FIG. 4 is a flow diagram describing a method 400 for controlling radiation conditions. FIGS. 5A-7C illustrate various applications of radiation control method 400, in accordance with some embodiments. For ease of description, method 400 will be described first. In each application, the operations illustrated in FIG. 4 will be referred to and method 400 will be described for the various applications illustrated in FIGS. 5A-7C. Additional operations can be performed between the various operations of method 400 and are omitted for simplicity. These additional operations are within the spirit and the scope of this disclosure. Moreover, not all operations may be required to perform the disclosure provided herein. Additionally, some of the operations can be performed simultaneously or in a different order than the ones shown in FIG. 4. Method 400 can be performed by radiation control system 100, in accordance with some embodiments.

Referring to FIG. 4, in operation 402, a radiation setting can be provided to configure a radiation device to provide radiation to a substrate undergoing a process operation in a process chamber of the radiation device. For example, the radiation setting can be provided by computing device 102 of FIG. 1. In some embodiments, the radiation setting can be provided by radiation device 114. The radiation setting can be provided to radiation device 114 to configure radiation device 114 to provide radiation to the substrate in process chamber 110. The radiation can be provided by radiation elements 108. The radiation setting can include a number of radiation elements 108 to be turned on, a level of heat (e.g., low, medium, and high) to be provided by radiation elements 108, a resistance of radiation elements 108, a tilt angle of radiation elements 108, and whether to employ cooling module 112. The radiation setting can depend on the various applications, such as the various applications illustrated in FIGS. 5A-7C.

Referring to FIG. 4, in operation 404, radiation energy data can be collected at one or more locations of the process chamber. For example, detection device 104 can be placed at different locations of process chamber 110. Detection device 104 can detect radiation energy data at the different locations. Detection device 104 can transmit the radiation energy data to computing device 102 or radiation device 114. In some embodiments, measurement data can be collected on the substrate. For example, measuring device 116 can measure data, such as CD data, on the substrate. The measurement can be in-situ and substantially in real time. The measurement can also be after the substrate completes the process operation in process chamber 110. Measuring device 116 can transmit the measurement data to computing device 102 or radiation device 114. The radiation energy data and the measurement data can be received by computing device 102 or radiation device 114 and analyzed by computing device 102 or radiation device 114. The radiation energy data can be energy data in Joules, or temperature data in Celsius, depending on the type of detection device 104. The radiation energy requirement can depend on the various radiation device setups, such as the various radiation device setups illustrated in FIGS. 5A-7C. The measurement data can include optical metrology data, optical inspection data, profilometer data, EIS data, SEM data, and/or TEM data. The measurement data can depend on the various applications, such as the various applications illustrated in FIGS. 5A-7C.

Referring to FIG. 4, in operation 406, a determination can be made whether a variance of the radiation energy data is above a predetermined threshold. In some embodiments, the radiation energy should be uniform across process chamber 110. A variance of the radiation energy data can then be obtained by comparing the radiation energy data to the average or to reference energy data. In some embodiments, the radiation energy can be based on a distribution. For example, the radiation energy can be high in the center of process chamber 110 and low at the edges of process chamber 110. A variance of the radiation energy data can then be obtained by comparing the radiation energy data to reference energy data for each location. The determination whether the variance of the radiation energy data is above the predetermined threshold can be made by computing device 102. If the variance is below the predetermined threshold, the same radiation setting can be provided to radiation device 114. In other words, operation 402 can be performed. In some embodiments, another determination based on the measurement data can be made, which is described below in operation 408, before the same radiation setting can be provided to radiation device 114. In response to the variance being above the predetermined threshold, computing device 102 or radiation device 114 can adjust the radiation setting based on the radiation energy data and method 400 can continue to operation 410. The predetermined threshold can depend on the various applications, such as the various applications illustrated in FIGS. 5A-7C.

Referring to FIG. 4, in operation 408, a determination can be made whether the difference between reference data and the measurement data is above a predetermined threshold. In some embodiments, the measurement should be uniform across the substrate. The difference can then be obtained by comparing the measurement data to one reference data. In some embodiments, the measurement can be based on a distribution. For example, the measurement can be high in the center of the substrate and low on the edges of the substrate, or the measurement can conform to a function, such as a sinusoidal, linear, and exponential function. A difference can then be obtained by comparing the measurement data to reference data for each measurement site on the substrate or each data point on a reference curve. The determination whether the difference between the reference data and the measurement data is above the predetermined threshold can be made by computing device 102 or radiation device 114. If the difference is below the predetermined threshold, the same radiation setting can be provided to radiation device 114. In other words, operation 402 can be performed. In response to the difference being above the predetermined threshold, computing device 102 or radiation device 114 can adjust the radiation setting based on the measurement data and method 400 can continue to operation 410. The predetermined threshold can depend on the various applications, such as the various applications illustrated in FIGS. 5A-7C.

Referring to FIG. 4, in operation 410, an adjusted radiation setting can be provided to configure the radiation device to provide adjusted radiation to the substrate. In some embodiments, the adjusted radiation setting can be provided to configure the radiation device to provide adjusted radiation to a different substrate that has yet to undergo the process operation. For example, the adjusted radiation setting can be provided by computing device 102 or radiation device 114. The adjusted radiation can be provided by radiation device 114 to process chamber 110. The process operation can be performed in process chamber 110. Based on the radiation energy data and the measurement data, computing device 102 or radiation device 114 can adjust the number of radiation elements 108 to be turned on, the level of heat (e.g., low, medium, and high) to be provided by radiation elements 108, the resistance of radiation elements 108, the tilt angle of radiation elements 108, and whether to employ cooling module 112. The adjusted radiation setting and the adjusted radiation conditions can depend on the various applications, such as the various applications illustrated in FIGS. 5A-7C. The adjusted radiation setting can assist in optimizing the radiation conditions in process chamber 110 and in achieving the measurement data within a predetermined range. If the radiation conditions are not optimized or if the measurement data remains outside the predetermined range, further adjustments can be made to the radiation settings. Because the radiation energy data and the measurement data can be monitored and fed into the radiation settings constantly or periodically, radiation conditions in process chamber 110 can be controlled to yield the measurement data within the predetermined range. The radiation energy data can also facilitate replacing aged radiation elements 108. Radiation control method 400 and radiation control system 100 can improve yield and quality.

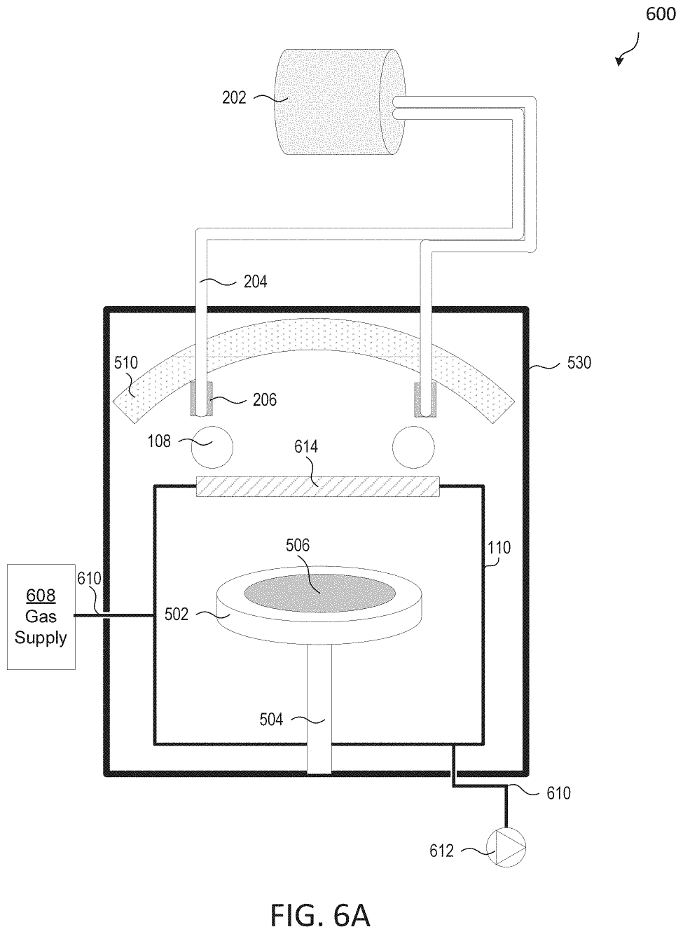

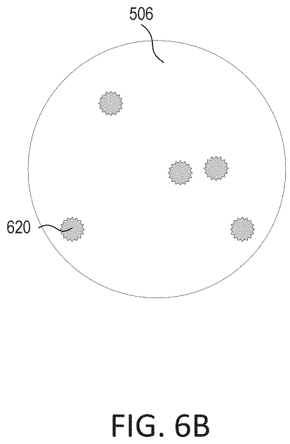

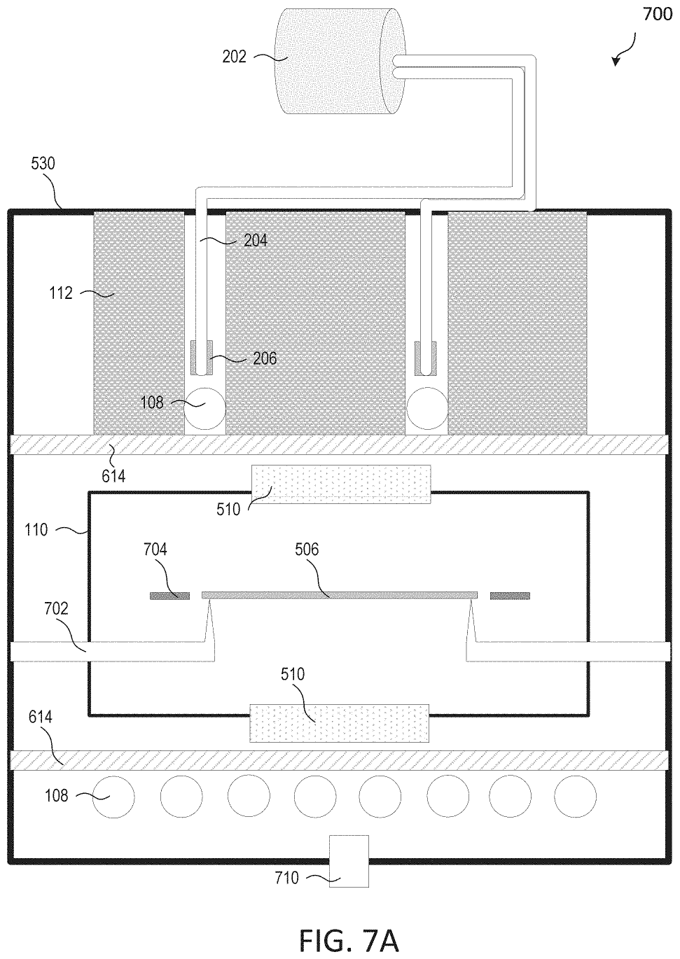

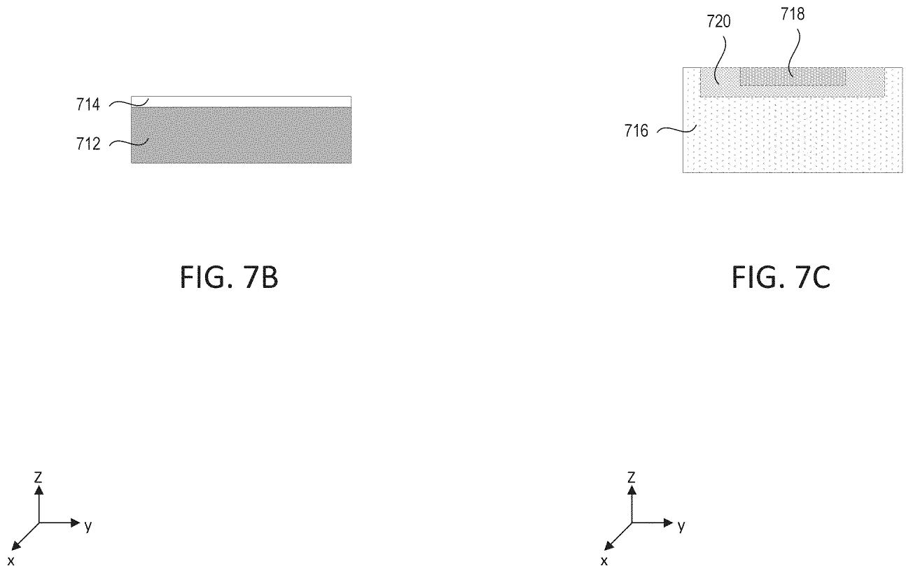

FIGS. 5A-7C illustrate various applications of radiation control method 400, in accordance with some embodiments. FIGS. 5A-5E illustrate an epitaxy process system and an application where radiation conditions are controlled to achieve desired epitaxy thicknesses. FIGS. 6A and 6B illustrate a UV process system and an application where radiation conditions are controlled to reduce contamination. FIGS. 7A-7C illustrate an RTA/RTP process system and two applications. The first application is where radiation conditions are controlled to achieve a desired oxide thickness. The second application is where radiation conditions are controlled to achieve desired dopant concentrations. The operations illustrated in FIG. 4 will be referred to and method 400 will be described for each application. The discussion of elements in FIGS. 1-3 and 5A-8 with the same annotations applies to each other, unless mentioned otherwise.

FIGS. 5A-5E illustrate an epitaxy process system and an application where radiation conditions are controlled to achieve desired epitaxy thicknesses. FIG. 5A illustrates an epitaxy process system 500. Epitaxy process system 500 can include radiation device chamber walls 530, radiation elements 108, cooling module 112, and reflectors 510. Radiation elements 108 can be halogen lamps. Epitaxy process system 500 can include process chamber 110, a substrate holder 502, and a substrate holder support 504. A substrate 506, such as a wafer, can be secured on substrate holder 502 by a mechanism, such as a vacuum suction mechanism. Substrate 506 can be a semiconductor material, such as Si, germanium (Ge), SiGe, a silicon-on-insulator (SOI) structure, and/or a combination thereof. Further, substrate 506 can be doped with p-type dopants, such as B, indium (In), aluminum (Al), and gallium (Ga), or n-type dopants, such as P and arsenic (As). Precursor gases 508 can be used to epitaxially grow an epitaxial layer, such as Si and SiGe, on substrate 506. For example, the epitaxial Si layer can be grown using source gases, such as silane (SiH₄), silicon tetrachloride (SiCl₄), trichlorosilane (TCS), and dichlorosilane (SiH₂Cl₂ or DSC). Hydrogen (H₂) can be used as a reactant gas to reduce the aforementioned source gases. The growth temperature during the epitaxial growth can range from about 700° C. to about 1250° C. depending on the gases used. For example, source gases with fewer chlorine atoms (e.g., like DSC) can require lower formation temperatures compared to source gases with more chlorine atoms, such as SiCl₄ or TCS. Radiation control can be important in growing a uniform epitaxial layer. If the radiation is not uniform, epitaxial layer can be non-uniform. If the radiation is too strong, epitaxial layer thickness can be too great. If the radiation is too weak, epitaxial layer thickness can be too small. A detection device including photodetector 202, optic fiber 204, and coating layer 206 can be used to detect radiation energy at different locations in process chamber 110. Even though FIG. 5A illustrates the detection device on the top portion of epitaxy process system 500, another detection device can be installed on the bottom portion of epitaxy process system 500.

FIG. 5B illustrates an arrangement of radiation elements 108. FIG. 5B illustrates radiation elements 108 can be arranged in a concentric circle. The concentric circle of radiation elements 108 can be placed at both the top and bottom portions of epitaxy process system 500. FIG. 5B illustrates 22 radiation elements but the number of radiation elements 108 can be between about 1 and about 100. Not every radiation element needs to be turned on to provide radiation. In some embodiments, a portion of radiation elements 108 needs to be turned on to provide a predetermined level of radiation energy. The tilt angles of radiation elements 108 can be adjusted to control radiation energy distribution. Not all radiation elements 108 are adjusted at one time to provide radiation control, in accordance with some embodiments. In some embodiments, tilt angles of a portion of radiation elements 108 are adjusted. For example, tilt angles of 8 out of the 22 radiation elements in FIG. 5B are adjusted, in accordance to some embodiments.

FIG. 5C illustrates an epitaxial layer on a substrate. For example, epitaxial layer 514 can be grown on substrate 506. Substrate 506 can be a semiconductor material, such as Si and SiGe. Substrate 506 can include structures, such as fin structures. Epitaxial layer 514 can be epitaxially grown with suitable precursor gases, and epitaxial layer 514 can be a semiconductor material, such as Si and SiGe. Thickness of epitaxial layer 514 can be between about 1 nm and 100 nm. FIG. 5D illustrates measurement data compared to reference data across a substrate. For example, as shown by reference data 516, thickness of epitaxial layer 514 can be smaller near the center of substrate 506 than near the edges of substrate 506. Measurement data 518 can show actual data measured on substrate 506 after substrate 506 completes the epitaxy process operation or during the epitaxial growth. There can be a difference between measurement data 518 and reference data 516. The difference can be caused by radiation non-uniformity. The difference can be used to feedback to radiation settings to control radiation. After the radiation settings are optimized, measurement data 518 should substantially overlap with reference data 516. In other words, the difference between reference data 516 and measurement data 518 should be below a predetermined threshold. FIG. 5D illustrates one exemplary functional representation of reference data 516. In some embodiments, reference data 516 can correspond to other functional representations, such as a linear, a parabolic, a sinusoidal, and an exponential function.

FIG. 5E illustrates a test substrate with thermal sensors. The initial radiation setting provided by computing device 102 can be determined based on historical empirical data, such as historical equipment setup data, historical equipment monitoring data, historical equipment health data, and historical measurement data. In some embodiments, a test substrate can be used to ascertain the initial conditions of the radiation device. In some embodiments, a test substrate can be similar to a production substrate. The test substrate can undergo the process operation and measurement data collected on the test substrate can be used to determine the initial radiation setting. FIG. 5E illustrates a test substrate with thermal sensors, in accordance with some embodiments. Test substrate 506 can be equipped with one or more thermal sensors 522 and one or more wires 524. Thermal sensors 522 can measure temperature data at different locations of substrate holder 502. Wires 524 can transmit the temperature data to computing device 102 for analysis. Based on the temperature data, computing device 102 can provide the initial radiation setting. In some embodiments, thermal sensors 522 can be bonded to substrate 506. In some embodiments, thermal sensors 522 can be a thermally-sensitive material sputtered on substrate 506. The test wafer can include other sensors.

In applying method 400 to the application illustrated by FIGS. 5A-5E, referring to FIG. 4, in operation 402, a radiation setting can be provided by computing device 102 to configure epitaxy process system 500 to provide radiation to substrate 506 undergoing the epitaxy process. In some embodiments, the radiation setting can be provided by epitaxy process system 500. The epitaxy process can be performed in process chamber 110. Substrate 506 can be secured on substrate holder 502. The radiation can be provided by radiation elements 108. Reflectors 510 can enhance the radiation in process chamber 110. The radiation setting can include a number of radiation elements 108 to be turned on, a level of heat (e.g., low, medium, and high) to be provided by radiation elements 108, a resistance of radiation elements 108, a tilt angle of radiation elements 108, and whether to employ cooling module 112.

Referring to FIG. 4, in operation 404, radiation energy data can be collected by detection device 104 at one or more locations in process chamber 110. Ends of optical fiber 204 can detect radiation energy data at the different locations. In some embodiments, optical fiber 204 can be embedded in cooling module 112 such that optical fiber 204 can be protected from overheating. The radiation energy data can be transmitted to computing device 102 or epitaxy process system 500. In some embodiments, measurement data can be collected on substrate 506. Referring to FIG. 5C, thickness of epitaxial layer 514 can be measured by measuring device 116, such as an optical spectrometer. The measurement can be in-situ and substantially in real time. The measurement can also be after substrate 506 completes the epitaxy process in process chamber 110. Measuring device 116 can transmit the measurement data to computing device 102 or epitaxy process system 500. The radiation energy data and the measurement data can be received by computing device 102 or epitaxy process system 500 and analyzed by computing device 102 or epitaxy process system 500. The radiation energy data can be energy data in Joules, or temperature data in Celsius, depending on the mechanism of photodetector 202.

Referring to FIG. 4, in operation 406, a determination can be made whether a variance of the radiation energy data is above a predetermined threshold. The radiation energy should be uniform across process chamber 110. A variance of the radiation energy data can then be obtained by comparing the radiation energy data to the average or to reference energy data. The determination whether the variance of the radiation energy data is above the predetermined threshold can be made by computing device 102 or epitaxy process system 500. If the variance is below the predetermined threshold, the same radiation setting can be provided to epitaxy process system 500. In other words, operation 402 can be performed. In some embodiments, another determination based on the measurement data can be made, which is described below in operation 408, before the same radiation setting can be provided to epitaxy process system 500. In response to the variance being above the predetermined threshold, computing device 102 or epitaxy process system 500 can adjust the radiation setting based on the radiation energy data and method 400 can continue to operation 410.

Referring to FIG. 4, in operation 408, a determination can be made whether the difference between reference data and the measurement data is above a predetermined threshold. Referring to FIG. 5D, the reference data can be plotted as reference data 516 across the substrate, and the actual measurement data can be plotted as measurement data 518 across the substrate. The difference can then be obtained by comparing measurement data 518 to reference data 516 for each measurement site on the substrate. The determination whether the difference between reference data 516 and measurement data 518 is above the predetermined threshold can be made by computing device 102 or epitaxy process system 500. If the difference is below the predetermined threshold, the same radiation setting can be provided to epitaxy process system 500. In other words, operation 402 can be performed. In response to the difference being above the predetermined threshold, computing device 102 or epitaxy process system 500 can adjust the radiation setting based on measurement data 518 and method 400 can continue to operation 410.

Referring to FIG. 4, in operation 410, an adjusted radiation setting can be provided by computing device 102 or epitaxy process system 500 to configure epitaxy process system 500 to provide adjusted radiation to the substrate. In some embodiments, the adjusted radiation setting can be provided to configure epitaxy process system 500 to provide adjusted radiation to a different substrate that has yet to undergo the epitaxy process operation. The adjusted radiation can be provided by radiation elements 108 to process chamber 110. The epitaxy process operation can be performed in process chamber 110. Based on measurement data 518 and the radiation energy data, computing device 102 or epitaxy process system 500 can adjust the number of radiation elements 108 to be turned on, the level of heat (e.g., low, medium, and high) to be provided by radiation elements 108, the resistance of radiation elements 108, the tilt angle of radiation elements 108, and whether to employ cooling module 112. The adjusted radiation setting can assist in optimizing the radiation conditions in process chamber 110 and in achieving the epitaxial layer thickness within a predetermined range. If the radiation conditions are not optimized or if the epitaxial layer thickness remains outside the predetermined range, further adjustments can be made to the radiation settings. Because the radiation energy data and the measurement data can be monitored and fed into the radiation settings constantly or periodically, radiation conditions in process chamber 110 can be controlled to yield the epitaxial layer thickness within the predetermined range. The radiation energy data can also facilitate replacing aged radiation elements 108. Radiation control method 400 and radiation control system 100 can improve yield and quality for the epitaxy process operation. The radiation energy data feedback can be substantially in real time. The epitaxial layer thickness data feedback can be substantially in real time because optical spectrometry can measure the thickness data in-situ and non-destructively. In some embodiments, the epitaxial layer thickness data feedback can be after the substrate completes the epitaxy process operation.

FIGS. 6A and 6B illustrate a UV process system and an application where radiation conditions are controlled to reduce contamination. FIG. 6A illustrates a UV process system 600. UV process system 600 can include radiation device chamber walls 530, radiation elements 108, reflectors 510, and a radiation window 614. Radiation elements 108 can be in an elongated shape, for example, along radiation window 614. Radiation window 614 can be made of a material that is transparent or translucent, such as quartz. Radiation window 614 can separate radiation elements 108 from process chamber 110 and allow light/radiation to pass through. UV process system 600 can include process chamber 110, substrate holder 502, and substrate holder support 504. UV process system 600 can include a gas supply 608, a pump 612, and gas pipes and/or conduits 610. Gas supply 608 can supply a process gas or a protective gas to process chamber 110 via gas pipes and/or conduits 610. Pump 612 can be a gas transfer pump or an entrapment pump. Pump 612 can extract exhaust gases from process chamber 110 via gas pipes and/or conduits 610. Pump 612 can provide a vacuum condition to process chamber 110 for some applications. Substrate 506 can be secured on substrate holder 502 by a mechanism, such as a vacuum suction mechanism. Substrate 506 can be a wafer and can have semiconductor structures on it. UV light can be used to oxidize organic contaminants and reduce surface contamination on substrate 506. Radiation control can be important in reducing contamination, such as organic contaminants, on substrate 506. If the radiation is non-uniform, surface cleaning can be non-uniform and some areas of substrate 506 can have too much contamination. If the radiation is too strong, the UV light can damage some semiconductor structures on substrate 506. If the radiation is too weak, the surface cleaning can be insufficient. The surface cleaning is insufficient if, for example, the percentage of contamination on substrate 506 after UV process is above a predetermined threshold. A detection device including photodetector 202, optic fiber 204, and coating layer 206 can be used to detect radiation energy at different locations in UV process system 600. Even though FIG. 6A illustrates the detection device on the top portion of UV process system 600, another detection device can be installed on the bottom portion of UV process system 600.

FIG. 6B illustrates contaminants on a substrate. For example, contaminants 620 can be found on substrate 506. Contaminants can be from the cleanroom environment, from a cleaning process operation, from an etching process operation, from a deposition process operation, and from a photolithography process operation. Substrate 506 can have semiconductor structures of small sizes, and the semiconductor structures can be damaged by the weight of contaminants 620. Contaminants 620 can also prevent the semiconductor structures from a next process operation, further causing defects and reducing yield. Contamination can be quantified by inspecting the total number of contaminants 620 or inspecting the total number of the semiconductor structures affected by contaminants 620. A percentage of the contamination can then be calculated by comparing the total number of the semiconductor structures affected by contaminants 620 with the total number of the semiconductor structures on substrate 506. There can be a difference between the percentage of the contamination and a predetermined threshold. The difference can be caused by radiation non-uniformity. The difference can be used to feedback to radiation settings to control radiation. After the radiation settings are optimized, the percentage of the contamination should be at and/or below the predetermined threshold.

In applying method 400 to the application illustrated by FIGS. 6A and 6B, referring to FIG. 4, in operation 402, a radiation setting can be provided by computing device 102 to configure UV process system 600 to provide radiation to substrate 506 undergoing the surface cleaning process. In some embodiments, the radiation setting can be provided by UV process system 600. The surface cleaning process can be performed in process chamber 110. Substrate 506 can be secured on substrate holder 502. The radiation can be provided by radiation elements 108. Reflectors 510 can enhance the radiation in process chamber 110. The radiation can pass through radiation window 614. The radiation setting can include a number of radiation elements 108 to be turned on, a level of heat (e.g., low, medium, and high) to be provided by radiation elements 108, and whether an aged radiation element 108 need to be replaced. The initial radiation setting can be based on historical equipment data, historical measurement data, and data obtained from a test substrate with thermal sensors.

Referring to FIG. 4, in operation 404, radiation energy data can be collected by detection device 104 at one or more locations in UV process system 600. Ends of optical fiber 204 can detect radiation energy data at the different locations. The radiation energy data can be transmitted to computing device 102 or UV process system 600. In some embodiments, inspection data can be collected on substrate 506. The percentage of the contamination can be inspected by measuring device 116, such as an optical inspection metrology tool. In some embodiments, a camera or a microscopy can be placed in process chamber 110 such that the inspection can be in-situ and substantially in real time. The inspection can also be after substrate 506 completes the surface cleaning process in process chamber 110. Measuring device 116 can transmit the inspection data to computing device 102 or UV process system 600. The radiation energy data and the inspection data can be received by computing device 102 or UV process system 600 and analyzed by computing device 102 or UV process system 600. The radiation energy data can be energy data in Joules, or temperature data in Celsius, depending on the mechanism of photodetector 202.

Referring to FIG. 4, in operation 406, a determination can be made whether a variance of the radiation energy data is above a predetermined threshold. The radiation energy should be uniform across process chamber 110. A variance of the radiation energy data can then be obtained by comparing the radiation energy data to the average or to reference energy data. The determination whether the variance of the radiation energy data is above the predetermined threshold can be made by computing device 102 or UV process system 600. If the variance is below the predetermined threshold, the same radiation setting can be provided to UV process system 600. In other words, operation 402 can be performed. In some embodiments, another determination based on the inspection data can be made, which is described below in operation 408, before the same radiation setting can be provided to UV process system 600. In response to the variance being above the predetermined threshold, computing device 102 or UV process system 600 can adjust the radiation setting based on the radiation energy data and method 400 can continue to operation 410.

Referring to FIG. 4, in operation 408, a determination can be made whether the percentage of the contamination is above a predetermined threshold. Referring to FIG. 6B, the percentage of the contamination can be calculated by comparing the total number of the semiconductor structures affected by contaminants 620 with the total number of the semiconductor structures on substrate 506. The determination whether the percentage of the contamination is above the predetermined threshold can be made by computing device 102 or UV process system 600. If the percentage of the contamination is below the predetermined threshold, the same radiation setting can be provided to UV process system 600. In other words, operation 402 can be performed. In response to the percentage of the contamination being above the predetermined threshold, computing device 102 or UV process system 600 can adjust the radiation setting based on the inspection data and method 400 can continue to operation 410.

Referring to FIG. 4, in operation 410, an adjusted radiation setting can be provided by computing device 102 or UV process system 600 to configure UV process system 600 to provide adjusted radiation to the substrate. In some embodiments, the adjusted radiation setting can be provided to configure UV process system 600 to provide adjusted radiation to a different substrate that has yet to undergo the surface cleaning process operation. The adjusted radiation can be provided by radiation elements 108 to process chamber 110. The surface cleaning process operation can be performed in process chamber 110. Based on the radiation energy data and the inspection data, computing device 102 or UV process system 600 can adjust the number of radiation elements 108 to be turned on, the level of heat (e.g., low, medium, and high) to be provided by radiation elements 108, and whether to send an instruction to replace an aged radiation element 108. The adjusted radiation setting can assist in optimizing the radiation conditions in process chamber 110 and in achieving the percentage of the contamination below a predetermined threshold. If the radiation conditions are not optimized or if the percentage of the contamination remains above the predetermined range, further adjustments can be made to the radiation settings. Because the radiation energy data and the inspection data can be monitored and fed into the radiation settings constantly or periodically, radiation conditions in process chamber 110 can be controlled to yield the percentage of the contamination below a predetermined threshold. The radiation energy data can also facilitate replacing aged radiation elements 108. Radiation control method 400 and radiation control system 100 can improve yield and quality for the surface cleaning process operation. The radiation energy data feedback can be substantially in real time. In some embodiments, the percentage of the contamination data feedback can be after the substrate completes the surface cleaning process operation.

FIGS. 7A-7C illustrate an RTA/RTP process system and two applications. The first application is where radiation conditions are controlled to achieve a desired oxide thickness, as shown in FIG. 7B. The second application is where radiation conditions are controlled to achieve desired dopant concentrations, as shown in FIG. 7C. FIG. 7A illustrates an RTA/RTP process system 700. RTA/RTP process system 700 can include radiation device chamber walls 530, radiation elements 108, reflectors 510, and radiation window 614. Radiation elements 108 can be halogen lamps. Radiation elements 108 can be embedded in cooling module 112, each radiation element 108 having its own slot. Each of the top portion and the bottom portion of RTA/RTP process system 700 can have a set of radiation elements 108, radiation window 614, and reflector 510. RTA/RTP process system 700 can include process chamber 110, a substrate support 702, and an edge ring 704. Substrate 506, such as a wafer, can be secured on substrate support 702 by the physical constraint of edge ring 704. A detection device including photodetector 202, optic fiber 204, and coating layer 206 can be used to detect radiation energy at different locations in RTA/RTP process system 700. Each optic fiber 204 can be placed in a slot with each radiation element 108. Each optic fiber 204 can then detect the radiation energy around each radiation element 108. Optic fiber 204 can also be protected from overheating by cooling module 112. Even though FIG. 7A illustrates the detection device on the top portion of RTA/RTP process system 700, another detection device can be installed on the bottom portion of RTA/RTP process system 700. RTA/RTP process system 700 can also include a thermal sensor 710, such as a pyrometer.

FIG. 7B illustrates an application where radiation conditions are controlled to achieve a desired oxide thickness. Material layer 712 can be a semiconductor material, such as Si, Ge, and SiGe, and oxide layer 714 can be SiOₓ, germanium oxide (GeOₓ), and silicon germanium oxide (SiGeOₓ). Material layer 712 can be a metal, such as Cu, cobalt (Co), a transition metal, and Al, and oxide layer 714 can be a metal oxide. In some embodiments, material layer 712 can be a material that needs to be oxidized by RTA/RTP process system 700, and oxide layer 714 can be an oxide layer corresponding to the oxidized material layer 712. Material layer 712 can be formed on substrate 506. RTA/RTP process system 700 can oxidize material layer 712 in ambient air or with an oxygen gas flow. The temperature during the oxide layer growth can range from about 200° C. to about 1300° C. Radiation control can be important in growing a uniform oxide layer. If the radiation is not uniform, oxide layer can be non-uniform. If the radiation is too strong, oxide layer thickness can be too great. If the radiation is too weak, oxide layer thickness can be too small. Thickness of oxide layer 714 can be between about 1 nm and 500 nm. There can be a difference between measurement data and reference data for the oxide layer thickness. The difference can be caused by radiation non-uniformity. The difference can be used to feedback to radiation settings to control radiation. After the radiation settings are optimized, the measurement data for the oxide layer thickness should overlap with the reference data. In other words, the difference between the reference data and the measurement data should be below a predetermined threshold.

In applying method 400 to the application illustrated by FIG. 7B, referring to FIG. 4, in operation 402, a radiation setting can be provided by computing device 102 to configure RTA/RTP process system 700 to provide radiation to material layer 712 undergoing the oxidation process. In some embodiments, the radiation setting can be provided by RTA/RTP process system 700. The oxidation process can be performed in process chamber 110. Material layer 712 can be formed on substrate 506, and substrate 506 can be secured on substrate support 702 by the physical constraint of edge ring 704. The radiation can be provided by radiation elements 108. Reflectors 510 can enhance the radiation in process chamber 110. The radiation can pass through radiation window 614. The radiation setting can include a number of radiation elements 108 to be turned on, a level of heat (e.g., low, medium, and high) to be provided by radiation elements 108, a resistance of radiation elements 108, whether to employ cooling module 112, and whether to send an instruction to replace an aged radiation element 108. The initial radiation setting can be based on historical equipment data, historical measurement data, and data obtained from a test substrate with thermal sensors.

Referring to FIG. 4, in operation 404, radiation energy data can be collected by detection device 104 at one or more locations in RTA/RTP process system 700. Ends of optical fiber 204 can detect radiation energy data at the different locations. In some embodiments, optical fiber 204 can be embedded in cooling module 112 such that optical fiber 204 can be protected from overheating. In some embodiments, each optical fiber 204 can be placed in a slot where each radiation element 108 is located. The radiation energy data can be transmitted to computing device 102 or RTA/RTP process system 700. In some embodiments, measurement data can be collected on substrate 506. Referring to FIG. 7B, thickness of oxide layer 714 can be measured by measuring device 116, such as an optical spectrometer. The measurement can be in-situ and substantially in real time. The measurement can also be after material layer 714 completes the oxidation process in process chamber 110. Measuring device 116 can transmit the measurement data to computing device 102 or RTA/RTP process system 700. The radiation energy data and the measurement data can be received by computing device 102 or RTA/RTP process system 700 and analyzed by computing device 102 or RTA/RTP process system 700. The radiation energy data can be energy data in Joules, or temperature data in Celsius, depending on the mechanism of photodetector 202.

Referring to FIG. 4, in operation 406, a determination can be made whether a variance of the radiation energy data is above a predetermined threshold. The radiation energy should be uniform across process chamber 110. A variance of the radiation energy data can then be obtained by comparing the radiation energy data to the average or to reference energy data. The determination whether the variance of the radiation energy data is above the predetermined threshold can be made by computing device 102 or RTA/RTP process system 700. If the variance is below the predetermined threshold, the same radiation setting can be provided to RTA/RTP process system 700. In other words, operation 402 can be performed. In some embodiments, another determination based on the measurement data can be made, which is described below in operation 408, before the same radiation setting can be provided to RTA/RTP process system 700. In response to the variance being above the predetermined threshold, computing device 102 or RTA/RTP process system 700 can adjust the radiation setting based on the radiation energy data and method 400 can continue to operation 410.

Referring to FIG. 4, in operation 408, a determination can be made whether the difference between reference data and the measurement data is above a predetermined threshold. Referring to FIG. 7B, oxide layer 714 can be desired to be uniform, and reference data can be determined. The actual measurement data of the thickness of oxide layer 714 can be measured by measuring device 116. The difference between the actual measurement data and the reference data can then be obtained by comparing the measurement data to the reference data for each measurement site on the substrate. The determination whether the difference between the reference data and the measurement data is above the predetermined threshold can be made by computing device 102 or RTA/RTP process system 700. If the difference is below the predetermined threshold, the same radiation setting can be provided to RTA/RTP process system 700. In other words, operation 402 can be performed. In response to the difference being above the predetermined threshold, computing device 102 or RTA/RTP process system 700 can adjust the radiation setting based on the measurement data and method 400 can continue to operation 410.

Referring to FIG. 4, in operation 410, an adjusted radiation setting can be provided by computing device 102 or RTA/RTP process system 700 to configure RTA/RTP process system 700 to provide adjusted radiation to the substrate. In some embodiments, the adjusted radiation setting can be provided to configure RTA/RTP process system 700 to provide adjusted radiation to a different substrate that has yet to undergo the epitaxy process operation. The adjusted radiation can be provided by radiation elements 108 to process chamber 110. The oxidation process operation can be performed in process chamber 110. Based on the radiation energy data and the measurement data, computing device 102 or RTA/RTP process system 700 can adjust the number of radiation elements 108 to be turned on, the level of heat (e.g., low, medium, and high) to be provided by radiation elements 108, the resistance of radiation elements 108, and whether to employ cooling module 112. The adjusted radiation setting can assist in optimizing the radiation conditions in process chamber 110 and in achieving the oxide layer thickness within a predetermined range. If the radiation conditions are not optimized or if the oxide layer thickness remains outside the predetermined range, further adjustments can be made to the radiation settings. Because the radiation energy data and the measurement data can be monitored and fed into the radiation settings constantly or periodically, radiation conditions in process chamber 110 can be controlled to yield the oxide layer thickness within the predetermined range. The radiation energy data can also facilitate replacing aged radiation elements 108. Radiation control method 400 and radiation control system 100 can improve yield and quality for the oxidation process operation. The radiation energy data feedback can be substantially in real time. The oxide layer thickness data feedback can be substantially in real time because optical spectrometry can measure the thickness data in-situ and non-destructively. In some embodiments, the oxide layer thickness data feedback can be after the substrate completes the oxidation process operation.

FIG. 7C illustrates another application where radiation conditions are controlled to achieve desired dopant concentrations. Intrinsic layer 716 can be a semiconductor material, such as Si, Ge, and SiGe. Doped layers 718 and 720 can be formed by doping intrinsic layer 716 with p-type dopants, such as B, In, Al, and Ga, or n-type dopants, such as P and As. Doped layers 718 and 720 can have different dopant concentrations. For example, doped layer 720 can have a dopant concentration between about 1×10²⁰ atoms/cm³ and about 1×10²¹ atoms/cm³. Doped layer 718 can have a dopant concentration between about 1×10₂₀ atoms/cm³ and about 3×10²² atoms/cm³. The difference in the dopant concentrations can be caused by the dopant implantation process operation. Intrinsic layer 716 and doped layers 718 and 720 can be formed on substrate 506. RTA/RTP process system 700 can anneal the doped layers 718 and 720 to redistribute the dopants such that the dopant concentration is uniform across doped layers 718 and 720. In some embodiments, a protective gas can be supplied to process chamber 110 to prevent oxidation during anneal. The temperature during anneal can range from about 200° C. to about 1300° C. Radiation control can be important in a post-implantation anneal to generate a uniform dopant concentration. If the radiation is not uniform, the dopant distribution can be non-uniform. If the radiation is too strong, the dopants can diffuse too far below the surface and the dopant concentration near the surface can be too low. If the radiation is too weak, the energy can be insufficient to drive the dopants to diffuse and the dopant distribution can be non-uniform. The dopant concentration of doped layers 718 and 720 can be about 1×10²⁰ atoms/cm³ and about 3×10²² atoms/cm³ after anneal. There can be a difference between the measured dopant concentration and reference data for the dopant concentration. The difference can be caused by radiation non-uniformity. The difference can be used to feedback to radiation settings to control radiation. After the radiation settings are optimized, the measured concentration should be substantially similar to the reference concentration. In other words, the difference between the reference data and the measurement data should be below a predetermined threshold.

In applying method 400 to the application illustrated by FIG. 7C, referring to FIG. 4, in operation 402, a radiation setting can be provided by computing device 102 to configure RTA/RTP process system 700 to provide radiation to doped layers 718 and 720 undergoing the post-implantation anneal process. In some embodiments, the radiation setting can be provided by RTA/RTP process system 700. The post-implantation anneal process can be performed in process chamber 110. Intrinsic layer 716 and doped layers 718 and 720 can be formed on substrate 506, and substrate 506 can be secured on substrate support 702 by the physical constraint of edge ring 704. The radiation can be provided by radiation elements 108. Reflectors 510 can enhance the radiation in process chamber 110. The radiation can pass through radiation window 614. The radiation setting can include a number of radiation elements 108 to be turned on, a level of heat (e.g., low, medium, and high) to be provided by radiation elements 108, a resistance of radiation elements 108, whether to employ cooling module 112, and whether to send an instruction to replace an aged radiation element 108. The initial radiation setting can be based on historical equipment data, historical measurement data, and data obtained from a test substrate with thermal sensors.

Referring to FIG. 4, in operation 404, radiation energy data can be collected by detection device 104 at one or more locations in RTA/RTP process system 700. Ends of optical fiber 204 can detect radiation energy data at the different locations. In some embodiments, optical fiber 204 can be embedded in cooling module 112 such that optical fiber 204 can be protected from overheating. In some embodiments, each optical fiber 204 can be placed in a slot where each radiation element 108 is located. The radiation energy data can be transmitted to computing device 102 or RTA/RTP process system 700. In some embodiments, measurement data can be collected on substrate 506. Referring to FIG. 7C, dopant concentrations of doped layers 718 and 720 can be measured by measuring device 116, such as an EIS. The measurement can be in-situ and substantially in real time. The measurement can also be after substrate 506 completes the post-implantation anneal process in process chamber 110. Measuring device 116 can transmit the measurement data to computing device 102 or RTA/RTP process system 700. The radiation energy data and the measurement data can be received by computing device 102 or RTA/RTP process system 700 and analyzed by computing device 102 or RTA/RTP process system 700. The radiation energy data can be energy data in Joules, or temperature data in Celsius, depending on the mechanism of photodetector 202.

Referring to FIG. 4, in operation 406, a determination can be made whether a variance of the radiation energy data is above a predetermined threshold. The radiation energy should be uniform across process chamber 110. A variance of the radiation energy data can then be obtained by comparing the radiation energy data to the average or to reference energy data. The determination whether the variance of the radiation energy data is above the predetermined threshold can be made by computing device 102 or RTA/RTP process system 700. If the variance is below the predetermined threshold, the same radiation setting can be provided to RTA/RTP process system 700. In other words, operation 402 can be performed. In some embodiments, another determination based on the measurement data can be made, which is described below in operation 408, before the same radiation setting can be provided to RTA/RTP process system 700. In response to the variance being above the predetermined threshold, computing device 102 or RTA/RTP process system 700 can adjust the radiation setting based on the radiation energy data and method 400 can continue to operation 410.

Referring to FIG. 4, in operation 408, a determination can be made whether the difference between a reference concentration and the measured concentration is above a predetermined threshold. Referring to FIG. 7C, the dopant concentration in doped layers 718 and 720 can be desired to be uniform, and the reference concentration can be determined. The actual measurement data of the dopant concentrations of doped layers 718 and 720 can be measured by measuring device 116. The difference between the actual dopant concentration and the reference concentration can then be obtained by comparing the measured concentration to the reference concentration for each measurement site on the substrate. The determination whether the difference between the reference concentration and the measured concentration is above the predetermined threshold can be made by computing device 102 or RTA/RTP process system 700. If the difference is below the predetermined threshold, the same radiation setting can be provided to RTA/RTP process system 700. In other words, operation 402 can be performed. In response to the difference being above the predetermined threshold, computing device 102 or RTA/RTP process system 700 can adjust the radiation setting based on the measured concentration and method 400 can continue to operation 410.

Referring to FIG. 4, in operation 410, an adjusted radiation setting can be provided by computing device 102 or RTA/RTP process system 700 to configure RTA/RTP process system 700 to provide adjusted radiation to the substrate. In some embodiments, the adjusted radiation setting can be provided to configure RTA/RTP process system 700 to provide adjusted radiation to a different substrate that has yet to undergo the epitaxy process operation. The adjusted radiation can be provided by radiation elements 108 to process chamber 110. The post-implantation anneal process operation can be performed in process chamber 110. Based on the radiation energy data and the measurement data, computing device 102 or RTA/RTP process system 700 can adjust the number of radiation elements 108 to be turned on, the level of heat (e.g., low, medium, and high) to be provided by radiation elements 108, the resistance of radiation elements 108, and whether to employ cooling module 112. The adjusted radiation setting can assist in optimizing the radiation conditions in process chamber 110 and in achieving the doped layer dopant concentration within a predetermined range. If the radiation conditions are not optimized or if the doped layer dopant concentration remains outside the predetermined range, further adjustments can be made to the radiation settings. Because the radiation energy data and the measurement data can be monitored and fed into the radiation settings constantly or periodically, radiation conditions in process chamber 110 can be controlled to yield the doped layer dopant concentration within the predetermined range. The radiation energy data can also facilitate replacing aged radiation elements 108. Radiation control method 400 and radiation control system 100 can improve yield and quality for the post-implantation anneal process operation. The radiation energy data feedback can be substantially in real time. The doped layer dopant concentration data feedback can be substantially in real time because EIS can measure the dopant concentration data in-situ. In some embodiments, the doped layer dopant concentration data feedback can be after the substrate completes the post-implantation anneal process operation.

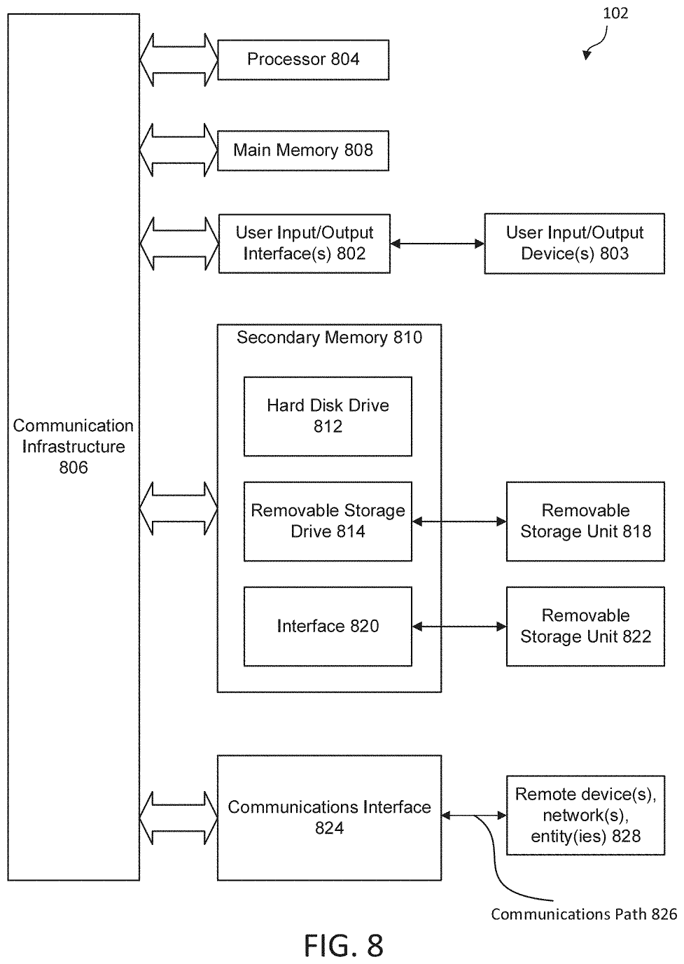

FIG. 8 is an illustration of an example computing device 102 of FIG. 1 in which various embodiments of the present disclosure can be implemented, according to some embodiments. Computing device 102 can be a computer capable of performing the functions and operations described herein, such as the operations of method 400 in FIG. 4. For example, and without limitation, computing device 102 can be capable of receiving, processing, and transmitting signals and commands. Computing device 102 can be used, for example, to receive radiation energy data and measurement data, analyze the radiation energy data and the measurement data, and adjust radiation settings based on the radiation energy data and the measurement data. Computing device 102 can be used, for example, to send radiation settings to radiation device 114 and configure radiation device 114 of FIG. 1 to provide radiation to process chamber 110 based on the radiation settings. Computing device 102 can be used, for example, to send radiation settings to adjustment device 106 and configure adjustment device 106 of FIG. 1 to adjust radiation elements 108 based on the radiation settings.

Computing device 102 includes one or more processors (also called central processing units, or CPUs), such as a processor 804. Processor 804 is connected to a communication infrastructure or bus 806. Computing device 102 also includes input/output device(s) 803, such as touch screens, monitors, keyboards, pointing devices, etc., that communicate with communication infrastructure or bus 806 through input/output interface(s) 802. Computing device 102 can receive instructions to implement functions and operations described herein—e.g., receiving the radiation energy data and the measurement data, analyzing the radiation energy data and the measurement data, adjusting the radiation settings, sending the radiation energy data and the measurement setting, configuring radiation device 114 and adjustment device 106, and method 400—via input/output device(s) 803. Computing device 102 can also include a main or primary memory 808, such as random access memory (RAM). Main memory 808 can include one or more levels of cache. Main memory 808 has stored therein control logic (e.g., computer software) and/or data. In some embodiments, the control logic (e.g., computer software) and/or data can include one or more of the functions described above with respect to receiving the radiation energy data and the measurement data, analyzing the radiation energy data and the measurement data, adjusting the radiation settings, sending the radiation energy data and the measurement setting, configuring radiation device 114 and adjustment device 106, and method 400.

Computing device 102 can also include one or more secondary storage devices or secondary memory 810. Secondary memory 810 can include, but is not limited to, a hard disk drive 812 and/or a removable storage device or drive 814. Removable storage drive 814 can be a floppy disk drive, a magnetic tape drive, a compact disk drive, an optical storage device, tape backup device, and/or any other storage device/drive.

Removable storage drive 814 can interact with a removable storage unit 818. Removable storage unit 818 includes a computer usable or readable storage device having stored thereon computer software (control logic) and/or data. Removable storage unit 818 can be a floppy disk, magnetic tape, compact disk, DVD, optical storage disk, and/or any other computer data storage device. Removable storage drive 814 reads from and/or writes to removable storage unit 818 in a well-known manner.

According to some embodiments, secondary memory 810 can include other means, instrumentalities or other approaches for allowing computer programs and/or other instructions and/or data to be accessed by computing device 102. Such means, instrumentalities or other approaches can include, but is not limited, a removable storage unit 822 and an interface 820. Examples of the removable storage unit 822 and the interface 820 can include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface. In some embodiments, secondary memory 810, removable storage unit 818, and/or removable storage unit 822 can include one or more of the functions described above with respect to the holder.

Computing device 102 can further include a communication or network interface 824. Communication interface 824 enables computing device 102 to communicate and interact with any combination of remote devices, remote networks, remote entities, etc. (individually and collectively referenced by reference number 828). For example, communication interface 824 can allow computing device 102 to communicate with element 828 (e.g., remote devices) over communications path 826, which can be wired and/or wireless, and which can include any combination of LANs, WANs, the Internet, etc. Control logic and/or data can be transmitted to and from computing device 102 via communication path 826.

The functions/operations in the preceding embodiments can be implemented in a wide variety of configurations and architectures. Therefore, some or all of the operations in the preceding embodiments—e.g., receiving the radiation energy data and the measurement data, analyzing the radiation energy data and the measurement data, adjusting the radiation settings, sending the radiation energy data and the measurement setting, configuring radiation device 114 and adjustment device 106, and method 400—can be performed in hardware, in software or both. In some embodiments, a tangible system or article of manufacture including a tangible computer useable or readable medium having control logic (software) stored thereon is also referred to herein as a computer program product or program storage device. This includes, but is not limited to, computing device 102, main memory 808, secondary memory 810 and removable storage units 818 and 822, as well as tangible articles of manufacture embodying any combination of the foregoing. Such control logic, when executed by one or more data processing devices (such as computing device 102), causes such data processing devices to operate as described herein. In some embodiments, computing device 102 includes hardware/equipment for the manufacturing of photomasks and circuit fabrication. For example, the hardware/equipment can be connected to or be part of element 828 (remote device(s), network(s), entity(ies) 828) of computing device 102.

The present disclosure is directed to a method (e.g., method 400) for providing radiation control in radiation devices (e.g., radiation device 114) based on radiation energy data and substrate measurement data feedback and an example system (e.g., system 100) for performing the method. A computing device (e.g., computing device 102) can provide an initial radiation setting to a radiation device. The initial radiation setting can be based on temperature data collected on a test substrate equipped with one or more thermal sensors. The initial radiation setting can be additionally and/or alternatively based on measurement data collected on a test substrate that has completed a process operation of interest. The radiation device can provide radiation to a substrate, such as a production wafer, based on the initial radiation setting. Detection devices (e.g., detection device 104) can be placed at different locations in the radiation device and collect radiation energy data. One exemplary detection device can include an optical fiber and a photodetector. The computing device can analyze the radiation energy data. If a variance of the radiation energy data is above a predetermined threshold, indicating the radiation energy distribution or non-uniformity is unacceptable, the computing device can adjust the radiation setting and provide the adjusted radiation setting to the radiation device. The radiation device can provide adjusted radiation based on the adjusted radiation setting to the substrate in substantially real time. The radiation device can also provide adjusted radiation based on the adjusted radiation setting to a subsequent substrate, where the subsequent substrate has yet to undergo the process operation. The radiation device can adjust radiation in different ways. For example, an adjustment device (e.g., adjustment device 106) can be used to adjust a tilt angle of a radiation element. One exemplary adjustment device can include a motor, such as a stepper motor, a spring, and a lever. In some embodiments, the radiation device can adjust a resistance of a radiation element. In some embodiments, the radiation device can generate an instruction to replace an aged radiation element.

Additionally and/or alternatively, substrate measurement data feedback can be used to control radiation conditions. After the substrate completes the process operation, a measuring device (e.g., measuring device 116) can collect data, such as critical dimension (CD) data, on the substrate. The measurement data can include optical metrology data, optical inspection data, profilometer data, spectrometry data, EIS data, SEM data, TEM data, and a combination thereof. In some embodiments, the measurement data can be thickness data of an epitaxial layer on the substrate. In some embodiments, the measurement data can be thickness data of an oxide layer on the substrate. In some embodiments, the measurement data can be dopant concentration data of a doped layer on the substrate. In some embodiments, the measurement data can be contamination percentage data of the substrate. The computing device can analyze the measurement data. If a difference between reference data and the measurement data on the substrate is above another predetermined threshold, also indicating the radiation energy distribution or non-uniformity is unacceptable, the computing device can further adjust the radiation setting and provide the adjusted radiation setting to the radiation device. The radiation device can then provide adjusted radiation based on the further adjusted radiation setting to a subsequent substrate. In some embodiments, the measurement device can collect in-situ data on the substrate, and the radiation device can provide adjusted radiation based on the further adjusted radiation setting to the substrate in substantially real time. In some embodiments, the radiation device can analyze the radiation energy data and the measurement data and adjust the radiation setting itself. The method and example system in the present disclosure can improve radiation distribution and uniformity in substantially real time. The improved radiation uniformity can reduce fabrication complexity, reduce defects, improve yield, and improve device reliability.

In some embodiments, a method includes sending a first setting to configure a radiation device to provide radiation to a substrate undergoing a process operation in a process chamber of the radiation device. The method further includes receiving radiation energy data measured at a plurality of locations of the process chamber and receiving measurement data measured on the substrate during the process operation. The method further includes in response to a variance of the radiation energy data being above a first predetermined threshold and in response to a difference between reference data and the measurement data being above a second predetermined threshold, sending a second setting to configure the radiation device to provide radiation to the substrate.

In some embodiments, a method includes receiving, by a radiation device, a radiation setting including a tilt angle of a radiation element of the radiation device and providing radiation, based on the radiation setting, to a first substrate undergoing a process operation in a process chamber of the radiation device. The method further includes in response to a variance of radiation energy data being above a predetermined threshold, receiving an adjustment in the tilt angle of the radiation element, where the radiation energy data is measured at a plurality of locations of the process chamber. The method further includes providing radiation, based on the adjusted radiation setting, to a second substrate that has yet to undergo the process operation.

In some embodiments, a system includes a computing device configured to generate first and second radiation settings. The system further includes a radiation device including one or more radiation elements and a process chamber, the radiation device configured to receive the first and second radiation settings and provide radiation, based on the first and second radiation settings, to a substrate undergoing a process operation in the process chamber. The system further includes a detection device configured to measure radiation energy data at a plurality of locations of the process chamber, where the second radiation setting is based on a variance of the radiation energy data being above a predetermined threshold. The system further includes an adjustment device including a spring, a lever, and a stepper motor, the adjustment device configured to adjust a tilt angle of the one or more radiation elements based on the second radiation setting.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
sending a first setting to configure a radiation device to provide radiation to a substrate undergoing a process operation in a process chamber of the radiation device;
receiving radiation energy data measured at a plurality of locations of the process chamber;
receiving measurement data measured on the substrate during the process operation; and
in response to a variance of the radiation energy data being above a first predetermined threshold and in response to a difference between reference data and the measurement data being above a second predetermined threshold, sending a second setting to configure the radiation device to provide radiation to the substrate.

2. The method of claim 1, further comprising:
receiving an other measurement data measured on the substrate after the substrate completes the process operation; and
in response to an other difference between an other reference data and the other measurement data being above a third predetermined threshold, sending a third setting to configure the radiation device to provide radiation to an other substrate that has yet to undergo the process operation.

3. The method of claim 1, wherein the measurement data comprises one or more of optical metrology data, optical inspection data, profilometer data, spectrometry data, electrochemical impedance spectroscopy (EIS) data, scanning electron microscopy (SEM) data, transmission electron microscopy (TEM) data, and a combination thereof.

4. The method of claim 1, wherein the measurement data comprises one or more of a thickness data of an epitaxial layer on the substrate, a thickness data of an oxide layer on the substrate, a dopant concentration data of a doped layer on the substrate, and a contamination percentage data of the substrate.

5. The method of claim 1, wherein sending the second setting comprises adjusting a tilt angle of a radiation element of the radiation device.

6. The method of claim 1, wherein sending the second setting comprises adjusting a resistance of a radiation element of the radiation device.

7. The method of claim 1, wherein sending the second setting comprises sending an instruction to replace a radiation element of the radiation device.

8. The method of claim 1, wherein the radiation energy data is measured by a detection device comprising an optical fiber and a photodetector.

9. The method of claim 1, wherein the first setting is based on measurement data measured on a test substrate that has completed the process operation before the substrate.

10. The method of claim 1, wherein the first setting is based on temperature data measured on a test substrate, wherein the test substrate comprises a plurality of thermal sensors.

11. A method, comprising:
receiving, by a radiation device, a radiation setting comprising a tilt angle of a radiation element of the radiation device;
providing radiation, based on the radiation setting, to a first substrate undergoing a process operation in a process chamber of the radiation device;
in response to a variance of radiation energy data being above a predetermined threshold, receiving an adjustment in the tilt angle of the radiation element, wherein the radiation energy data is measured at a plurality of locations of the process chamber; and
providing radiation, based on the adjusted radiation setting, to a second substrate that has yet to undergo the process operation.

12. The method of claim 11, wherein receiving the adjustment in the tilt angle comprises adjusting the tilt angle of the radiation element using an adjustment device comprising a spring, a lever, and a stepper motor, wherein the radiation element comprises a halogen lamp.

13. The method of claim 11, further comprising in response to a difference between reference data and measurement data being above an other predetermined threshold, receiving an other adjustment in the radiation setting, wherein the measurement data is measured on the first substrate.

14. The method of claim 13, wherein receiving the other adjustment in the radiation setting comprises adjusting a resistance of an other radiation element, wherein the other radiation element comprises a halogen lamp.

15. The method of claim 13, wherein receiving the other adjustment in the radiation setting comprises receiving an instruction to replace an other radiation element, wherein the other radiation element comprises a halogen lamp or an ultraviolet (UV) light.

16. The method of claim 11, wherein receiving the adjustment in the tilt angle comprises measuring the radiation energy data with a detection device comprising an optical fiber and a photodetector.

17. A system, comprising:
a computing device configured to generate first and second radiation settings;
a radiation device comprising one or more radiation elements and a process chamber, the radiation device configured to:
receive the first and second radiation settings; and
provide radiation, based on the first and second radiation settings, to a substrate undergoing a process operation in the process chamber;
a detection device configured to measure radiation energy data at a plurality of locations of the process chamber, wherein the second radiation setting is based on a variance of the radiation energy data being above a predetermined threshold; and
an adjustment device comprising a spring, a lever, and a stepper motor, the adjustment device configured to adjust a tilt angle of the one or more radiation elements based on the second radiation setting.

18. The system of claim 17, further comprising a measurement device configured to measure data on the substrate after the substrate completes the process operation, wherein the computing device is further configured to generate a third radiation setting in response to a difference between reference data and the measured data being above an other predetermined threshold.

19. The system of claim 17, wherein the detection device comprises an optical fiber and a photodetector, and wherein the radiation device further comprises a cooling module that protects the detection device from overheating.

20. The system of claim 17, wherein the one or more radiation elements comprise a halogen lamp.
